(19) United States
(12) Patent Application Publication
(10) Pub. No.: US 2025/0031334 A1
(43) Pub. Date: Jan. 23, 2025

(54) ECU FOR VEHICLE

(71) Applicant: HL Mando Corporation, Pyeongtaek-si (KR)

(72) Inventor: Jihwan KIM, Pyeongtaek-si (KR)

(21) Appl. No.: 18/394,239

(22) Filed: Dec. 22, 2023

(30) Foreign Application Priority Data
Jul. 19, 2023 (KR) 10-2023-0093747

(51) Int. Cl. H05K 7/14; H05K 5/00

(52) U.S. Cl. CPC H05K 7/1402; H05K 5/0073; H05K 7/1427

(57) ABSTRACT

Embodiments provide an ECU for a vehicle, including a housing body which has a body locking portion formed to protrude outward from a periphery of an upper part and on which a printed circuit board is seated; and a housing cover which has a cover locking portion at a lower end thereof coupled to the housing body so that the body locking portion is inserted and coupled into the cover locking portion.

### CROSS-REFERENCE TO RELATED APPLICATION

This application claims priority from Korean Patent Application No. 10-2023-0093747, filed on Jul. 19, 2023, which is hereby incorporated by reference for all purposes as if fully set forth herein.

### BACKGROUND

### Field

The present embodiments relate to an ECU (electronic control unit) for a vehicle, and more specifically, to an ECU for a vehicle, which can increase the fixing force of a housing body and a housing cover to prevent fluctuation and rattle noise, can simplify the assembly process of the housing body and the housing cover, and can reduce a dimension error and an assembly error.

### Description of Related Art

The ECU for a vehicle has a structure in which a housing body and a housing cover are assembled. In the ECU, the housing body and the housing cover are likely to fluctuate due to complex factors such as vibration caused by long-term driving and shock transferred from a road surface during driving of the vehicle, and thus, a problem may arise in that rattle noise is generated.

In addition, problems are caused in that the assembly process of the housing body and housing cover of the ECU is complicated and a dimension error and an assembly error are large.

Therefore, there is a need for research to prevent rattle noise due to fluctuation of the housing body and housing cover of the ECU and to simplify the assembly process of the housing body and housing cover.

### BRIEF SUMMARY

Accordingly, embodiments have been made under the above-described background, and may provide an ECU for a vehicle, which can increase the fixing force of a housing body and a housing cover to prevent fluctuation and rattle noise.

In addition, embodiments may provide an ECU for a vehicle, which can simplify the assembly process of a housing body and a housing cover and can reduce a dimension error and an assembly error.

Objects to be achieved by embodiments are not limited to the aforementioned objects, and those skilled in the art may clearly understand other objects from the following descriptions.

In an embodiment, an ECU for a vehicle may include: a housing body which has a body locking portion formed to protrude outward from a periphery of an upper part and on which a printed circuit board is seated; and a housing cover which has a cover locking portion at a lower end thereof coupled to the housing body so that the body locking portion is inserted and coupled into the cover locking portion.

In an embodiment, an ECU for a vehicle may include: a housing body in which an upper part and a lower part are connected in a stepped manner, a printed circuit board is seated on the upper part and a periphery of the lower part has a body locking portion formed to protrude upward and be separated from an outer surface of the upper part; and a housing cover which has a cover locking portion at a lower end thereof coupled to the outer surface of the upper part of the housing body so that the body locking portion is inserted and coupled into the cover locking portion.

According to the embodiments, in an ECU for a vehicle, the fixing force of a housing body and a housing cover may be increased to prevent fluctuation and rattle noise.

In addition, according to the embodiments, in an ECU for a vehicle, the assembly process of a housing body and a housing cover may be simplified, and a dimension error and an assembly error may be reduced.

### DESCRIPTION OF DRAWINGS

The above and other objects, features, and advantages of the present disclosure will be more clearly understood from the following detailed description, taken in conjunction with the accompanying drawings, in which:

FIG. 1 is a perspective view illustrating a part of an ECU for a vehicle in accordance with an embodiment;

FIG. 2 is a plan view of FIG. 1;

FIG. 3 is an exploded perspective view of FIG. 1;

FIG. 4 is a perspective view illustrating a part of the ECU for a vehicle in accordance with the embodiment;

FIGS. 5 to 7 are front views illustrating a part of the ECU for a vehicle in accordance with the embodiment;

FIG. 8 is a perspective view illustrating a part of the ECU for a vehicle in accordance with the embodiment;

FIG. 9 is a cross-sectional view illustrating a part of the ECU for a vehicle in accordance with the embodiment;

FIG. 10 is an exploded perspective view illustrating a part of an ECU for a vehicle in accordance with an embodiment; and

FIG. 11 is a cross-sectional view illustrating a part of the ECU for a vehicle in accordance with the embodiment.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

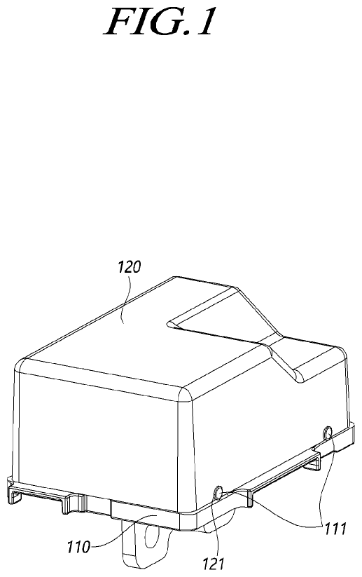

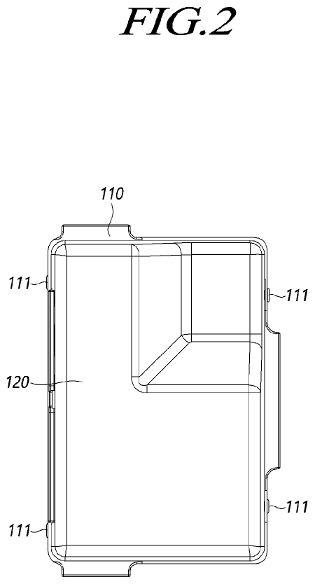

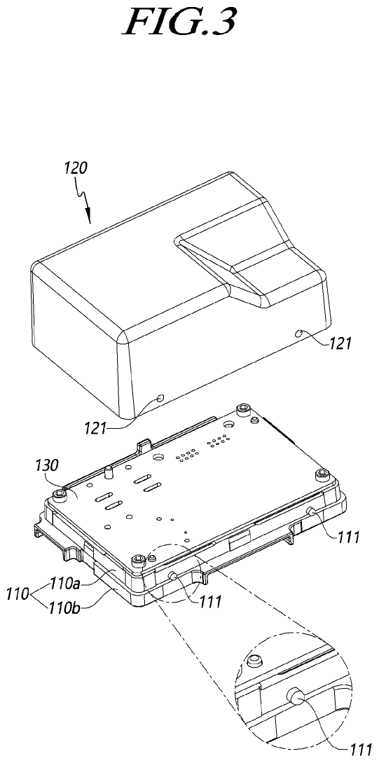

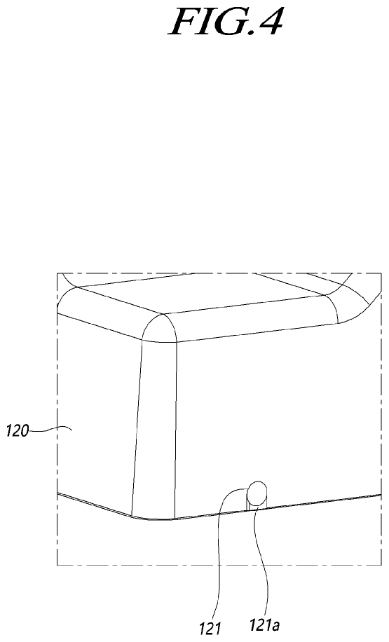

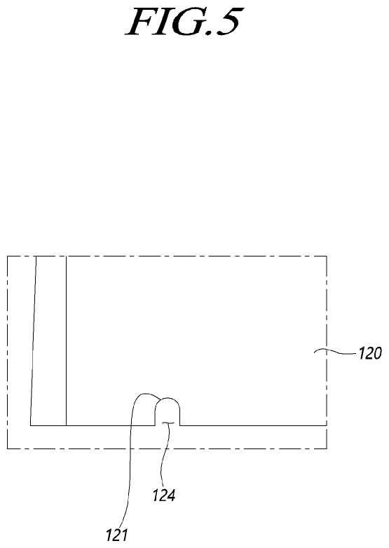

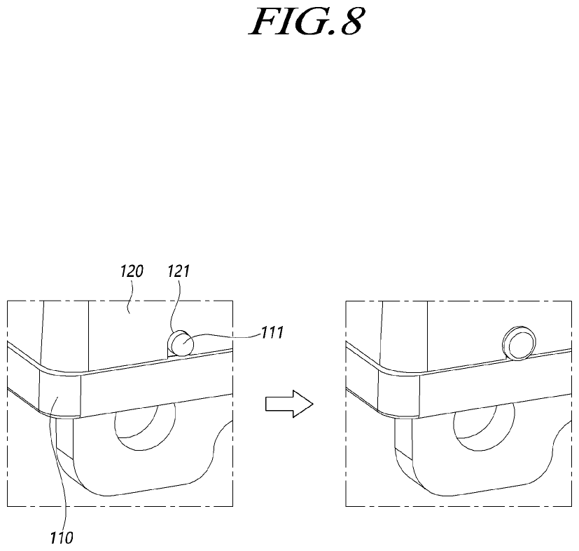

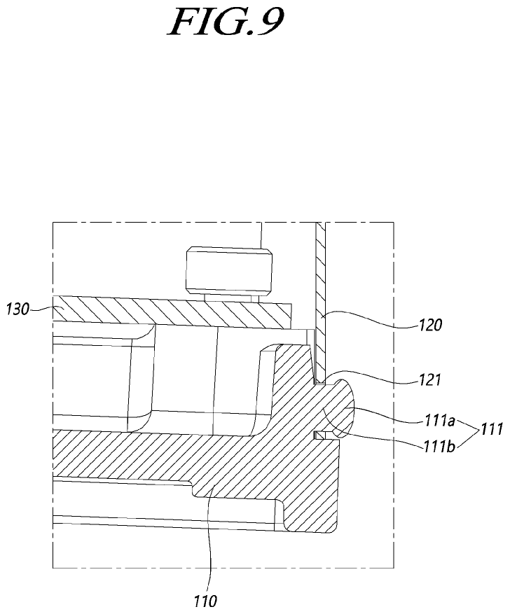

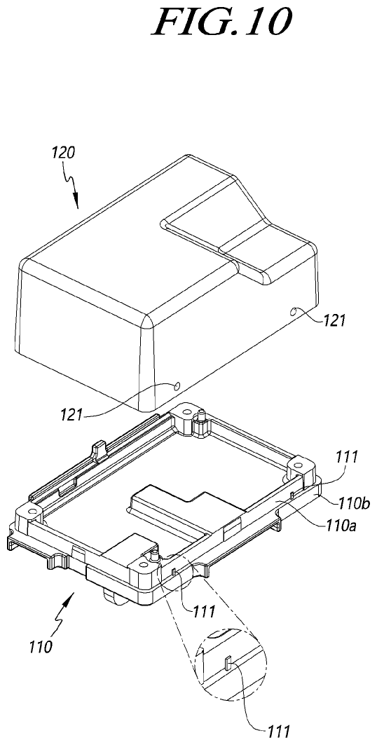

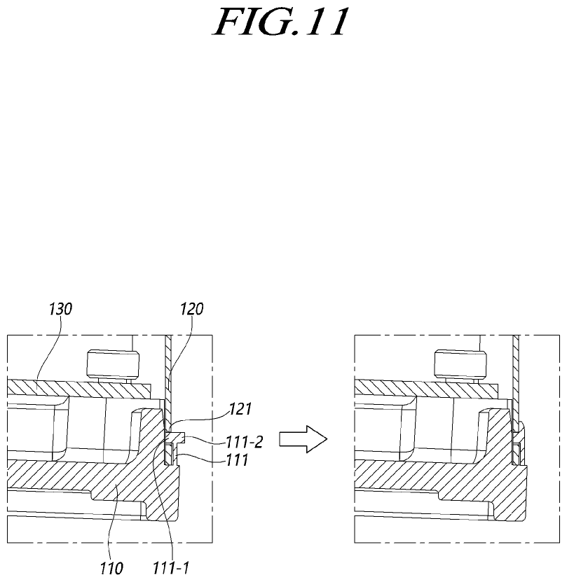

FIG. 1 is a perspective view illustrating a part of an ECU for a vehicle in accordance with an embodiment, FIG. 2 is a plan view of FIG. 1, FIG. 3 is an exploded perspective view of FIG. 1, FIG. 4 is a perspective view illustrating a part of the ECU for a vehicle in accordance with the embodiment, FIGS. 5 to 7 are front views illustrating a part of the ECU for a vehicle in accordance with the embodiment, FIG. 8 is a perspective view illustrating a part of the ECU for a vehicle in accordance with the embodiment, FIG. 9 is a cross-sectional view illustrating a part of the ECU for a vehicle in accordance with the embodiment, FIG. 10 is an exploded perspective view illustrating a part of an ECU for a vehicle in accordance with an embodiment, and FIG. 11 is a cross-sectional view illustrating a part of the ECU for a vehicle in accordance with the embodiment.

First, referring to FIGS. 1 to 9, the ECU for a vehicle in accordance with the embodiment includes a housing body 110 which has body locking portions 111 formed to protrude outward from the periphery of an upper part 110a and on which a printed circuit board 130 is seated, and a housing cover 120 which has cover locking portions 121 at a lower end thereof coupled to the housing body 110 so that the body locking portions 111 are inserted and coupled into the cover locking portions 121.

The ECU 110 and 120 mounted to a vehicle steers the vehicle by rotating wheels by sliding a rack bar by the medium of a worm wheel reducer or a belt reducer through controlling a motor. Since this is a general configuration in the technical field to which the embodiment pertains, detailed description thereof will be omitted.

Such an ECU 110 and 120 for a vehicle largely includes the housing cover 120 and the housing body 110. The housing cover 120 for protecting the printed circuit board 130 and for connection to a power supply unit and the motor mounted to the vehicle is coupled to the upper end of the housing body 110.

The printed circuit board 130 is seated on and coupled to the housing body 110 which is substantially formed in a box shape, and the housing cover 120 is coupled to the upper part 110a of the housing body 110.

The periphery of the upper part 110a of the housing body 110 has the body locking portions 111 which protrude outward, and the housing cover 120 has the cover locking portions 121 at the lower end thereof coupled to the housing body 110 so that the body locking portions 111 of the housing body 110 are inserted and coupled into the cover locking portions 121.

At least two body locking portions 111 may be provided along the periphery of the upper part 110a of the housing body 110 to be spaced apart from each other.

At least two body locking portions 111 may be provided at opposite positions on the housing body 110, that is, on the periphery of the upper part 110a on both sides disposed parallel to each other as illustrated in FIG. 2.

In the present embodiment, FIG. 2 illustrates as an example that two body locking portions 111 are provided at peripheral positions, respectively, on the upper part 110a of the housing body 110 which face each other, adjacent to each short edge of the upper part 110a of the housing body 110.

As illustrated in FIG. 3, the body locking portions 111 are formed to protrude in pillar shapes perpendicularly to the outer surface of the periphery of the upper part 110a of the housing body 110.

The cover locking portions 121 may be formed in the shapes of holes into which the body locking portions 111 are inserted.

In this case, when assembling the housing cover 120 to the housing body 110, the housing cover 120 is slid downward as the lower end of the housing cover 120 is elastically deformed by the body locking portions 111, and the body locking portions 111 are coupled into the cover locking portions 121 of hole shapes.

In order for easier assembly, as illustrated in FIG. 4, the inner surface of the housing cover 120 may have a guide groove 121a into which the body locking portion 111 is inserted to be guided by being slid.

The guide groove 121a is formed in a shape which is recessed from the cover locking portion 121 to the lower end of the housing cover 120, and is connected to the cover locking portion 121 to guide the assembly direction of the housing cover 120.

After being inserted into the cover locking portion 121, the body locking portion 111 may be caulked and fixed to the outside of the housing cover 120.

As illustrated in FIG. 5, the cover locking portion 121 may have an opening 124 which is formed as the lower end of the housing cover 120 is cut to be open in the direction of the housing body 110.

Therefore, when assembling the housing cover 120 to the housing body 110, as the body locking portion 111 is inserted into and slid along the opening 124 of the cover locking portion 121, the body locking portion 111 is supported by and coupled to the end of the cover locking portion 121.

After the body locking portion 111 is coupled to the cover locking portion 121, the body locking portion 111 may be caulked and fixed to the outside of the housing cover 120.

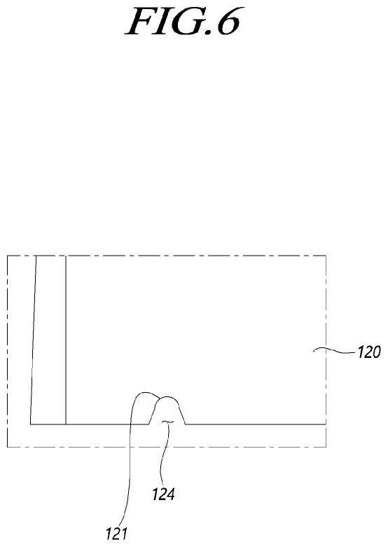

As illustrated in FIG. 6, the cover locking portion 121 may be formed so that the width of an opening 124 gradually increases toward the lower end of the housing body 110.

In this case, when assembling the housing cover 120, setting of an initial assembly position with the body locking portion 111 becomes easy, and assembly may be easily performed even if there is an error in the size of the cover locking portion 121 or the body locking portion 111.

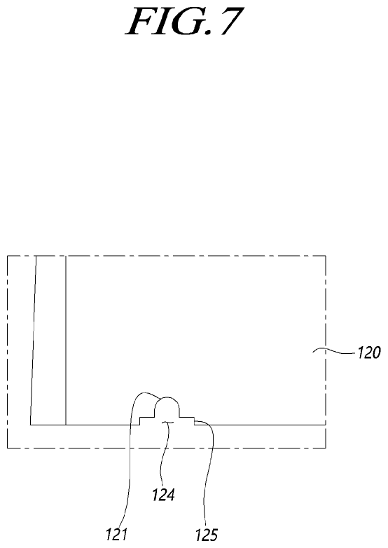

As illustrated in FIG. 7, the cover locking portion 121 may have an extended opening 125 which is open to extend toward one side or both sides of the lower end of the housing cover 120.

The extended opening 125 may be formed so that an opening 124 extends toward one side or both sides of the lower end of the housing cover 120, and the present embodiment illustrates as an example a case where the opening 124 extends toward both ends of the lower end of the housing cover 120.

Even in this case, when assembling the housing cover 120, setting of an initial assembly position with the body locking portion 111 becomes easy, and assembly may be easily performed even if there is an error in the size of the cover locking portion 121 or the body locking portion 111.

As illustrated in the right drawing of FIG. 8, the body locking portion 111 may be inserted into the opening 124 of the cover locking portion 121 and be then caulked and fixed to the outside of the housing cover 120.

That is to say, in a state in which the cover locking portion 121 is coupled to the body locking portion 111, the housing cover 120 is fixed to the housing body 110 through caulking of plastically deforming the body locking portion 111 protruding out of the housing cover 120 and compressing the body locking portion 111 against the outside of the housing cover 120.

As illustrated in FIG. 9, the body locking portion 111 may include a support portion 111b which is inserted through the opening of the cover locking portion 121, and a head portion 111a which is formed to be enlarged in a radial direction from the circumferential outer surface of the support portion 111b.

The support portion 111b is formed in a pillar shape with the same diameter, and is formed to be the same as the width of the opening 124 of the cover locking portion 121.

Therefore, if the body locking portion 111 is plastically deformed by caulking in a state in which the cover locking portion 121 is coupled to the body locking portion 111, the housing cover 120 is not released from a fixed position even though a load or vibration is transferred from the outside.

Furthermore, since the head portion 111a is formed by being enlarged on the circumferential outer surface of the support portion 111b, an area of the housing body 110 in close contact with the outer surface of the housing cover 120 increases after caulking, whereby the fixing force of the housing cover 120 is increased.

Referring to FIGS. 10 and 11 together with FIGS. 1 to 9, an ECU for a vehicle in accordance with an embodiment may include a housing body 110 in which an upper part 110a and a lower part 110b are connected in a stepped manner, a printed circuit board 130 is seated on the upper part 110a and the periphery of the lower part 110b has body locking portions 111 formed to protrude upward and be separated from the outer surface of the upper part 110a, and a housing cover 120 which has cover locking portions 121 at a lower end thereof coupled to the outer surface of the upper part 110a of the housing body 110 so that the body locking portions 111 are inserted and coupled into the cover locking portions 121.

At least two body locking portions 111 may be provided along the periphery of the lower part 110b of the housing body 110 to be spaced apart from each other.

As illustrated in FIG. 2, at least two body locking portions 111 may be provided at peripheral positions, respectively, on the lower part 110b of the housing body 110 which face each other, adjacent to each short edge of the lower part 110b of the housing body 110.

The cover locking portions 121 may be formed in the shapes of holes into which the ends of the body locking portions 111 are inserted.

In this case, as illustrated in FIG. 11, the body locking portion 111 may be inserted into the cover locking portion 121 and be then caulked and fixed to the outside of the housing cover 120.

The inner surface of the body locking portion 111 may have an inner protruding end 111-1 which protrudes in the direction of the cover locking portion 121.

In this case, when assembling the housing cover 120 to the housing body 110, as the body locking portion 111 is elastically deformed outward by the housing cover 120, the inner protruding end 111-1 is coupled into the cover locking portion 121 of a hole shape.

After the inner protruding end 111-1 is inserted into the cover locking portion 121, the inner protruding end 111-1 and the body locking portion 111 may be caulked and fixed.

The outer surface of the body locking portion 111 may have an outer protruding end 111-2 which protrudes outward. Due to this fact, after the body locking portion 111 and the outer protruding end 111-2 are caulked, an area of the housing body 110 in close contact with the outer surface of the housing cover 120 increases, whereby the fixing force of the housing cover 120 is increased.

As is apparent from the above description, according to the embodiments, in an ECU for a vehicle, the fixing force of a housing body and a housing cover may be increased to prevent fluctuation and rattle noise.

In addition, according to the embodiments, in an ECU for a vehicle, the assembly process of a housing body and a housing cover may be simplified, and a dimension error and an assembly error may be reduced.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure. Thus, the scope of the present disclosure is not limited to the embodiments shown, but is to be accorded the widest scope consistent with the claims.

What is claimed is:

1. An electronic control unit for a vehicle, the electronic control unit comprising:
a housing body which has a body locking portion protruding outward from a periphery of an upper part of the housing body and on which a printed circuit board is seated; and
a housing cover which has a cover locking portion at a lower end thereof,
wherein the body locking portion is configured to be inserted and coupled into the cover locking portion to couple the housing cover to the housing body.

2. The electronic control unit of claim 1, wherein
the housing body has at least two body locking portions including the body locking portion,
the at least two body locking portions are spaced apart from each other along the periphery of the upper part of the housing body.

3. The electronic control unit of claim 2, wherein the at least two body locking portions are provided at opposite positions on the periphery of the upper part of the housing body.

4. The electronic control unit of claim 1, wherein the body locking portion is protrudes in a pillar shape perpendicularly to an outer surface of the periphery of the upper part of the housing body.

5. The electronic control unit of claim 4, wherein the cover locking portion is a hole into which the body locking portion is configured to be inserted.

6. The electronic control unit of claim 5, wherein an inner surface of the housing cover has a guide groove configured to guide the body locking portion to be inserted to a lower end of the cover locking portion.

7. The electronic control unit of claim 5, wherein, in a state that the body locking portion is inserted into the cover locking portion, the body locking portion is caulked and fixed to an outer side of the housing cover.

8. The electronic control unit of claim 4, wherein the cover locking portion is a cutout at the lower end of the housing cover and is open in a direction facing the housing body in a state that the housing cover is coupled to the housing body.

9. The electronic control unit of claim 8, wherein a width of the cutout gradually increases toward the lower end of the housing cover.

10. The electronic control unit of claim 8, wherein the cover locking portion has an extended opening extending from one side of the cutout in a width direction of the cutout.

11. The electronic control unit of claim 8, wherein the cover locking portion has an extended opening extending from two sides of the cutout in a width direction of the cutout.

12. The electronic control unit of claim 8, wherein, in a state that the body locking portion is inserted into the cutout of the cover locking portion, the body locking portion is caulked and fixed to an outer side of the housing cover.

13. The electronic control unit of claim 8, wherein the body locking portion comprises:
a support portion configured to be inserted through the cutout of the cover locking portion; and
a head portion enlarged in a radial direction from an outer circumferential surface of the support portion.

14. An electronic control unit for a vehicle, the electronic control unit comprising:
a housing body including an upper part and a lower part, the upper part and the lower part being connected in a stepped manner, wherein
a printed circuit board is seated on the upper part, and
a body locking portion protrudes upward from a periphery of the lower part and is separated from an outer surface of the upper part; and
a housing cover including a cover locking portion at a lower end thereof, wherein the body locking portion configured to be inserted and coupled into the cover locking portion to couple the housing cover to the outer surface of the upper part of the housing body.

15. The electronic control unit of claim 14, wherein at least two body locking portions including the body locking portion are spaced apart from each other along the periphery of the lower part of the housing body.

16. The electronic control unit of claim 15, wherein the at least two body locking portions are provided at opposite positions at the periphery of the lower part of the housing body.

17. The electronic control unit of claim 14, wherein the cover locking portion is a hole into which an end of the body locking portion is configured to be inserted.

18. The electronic control unit of claim 17, wherein, in a state that the body locking portion is inserted into the cover locking portion, the body locking portion is caulked and fixed to an outer side of the housing cover.

19. The electronic control unit of claim 18, wherein the body locking portion has an inner protruding end protruding toward an inner side of the housing cover in a state that the housing cover is coupled to the outer surface of the upper part of the housing body.

20. The electronic control unit of claim 19, wherein the body locking portion has an outer protruding end protruding toward the outer side of the housing cover in the state that the housing cover is coupled to the outer surface of the upper part of the housing body.
